(19) United States
(12) Patent Application Publication
(10) Pub. No.: US 2007/0072332 A1
(43) Pub. Date: Mar. 29, 2007

(54) Semiconductor radiation detectors and method for fabrication thereof

(76) Inventor: Josef Kemmer, Oberschleissheim (DE)

Correspondence Address: Jeffrey S. Habib, Esq.;Hooker & Habib, P.C., Suite 304, 100 Chestnut St, Harrsiburg, PA, 17101, US

(21) Appl. No.: 11/234,888

(22) Filed: Sep. 26, 2005

(51) Int. Cl. H01L 21/00

(52) U.S. Cl. 438/56

(57) ABSTRACT

The invention relates to a method for fabricating semiconductor radiation detectors comprising a bulk of a first conductivity type for detecting radiation with further semiconductor layers of a second and a first conductivity type patterned thereon, at least one of the further semiconductor layers being deposited by epitaxy. The invention relates further to integration of electronic components in radiation detectors in employing epitaxy, as well as to radiation detectors of a great variety in which epi layers are deposited as thin radiation entrance windows, as guard structures and as resistive layers.

### FIELD OF THE INVENTION

The present invention relates generally to semiconductor radiation detectors, and for example, to a method for fabrication of a semiconductor radiation detector. Such semiconductor radiation detectors find application, for example, in detecting and spectroscopic analysis of electromagnetic radiation and ionising corpuscular radiation.

### BACKGROUND OF THE INVENTION

Such radiation detectors, preferably silicon-based, are commercially available as pn-diodes, silicon strip detectors (SSDs) silicon drift detectors (SDDs), charge coupled devices (CCDs), pixel detectors, etc, all of which have been described in many publications, patents and patent applications such as DE0003507763A1, DE0003415439A1, U.S. Pat. No. 4,688,067 A, U.S. Pat. No. 5,773,829 A, U.S. Pat. No. 6,455,858 B1, U.S. Pat. No. 4,837,607 A, U.S. Pat. No. 4,885,620 A and U.S. Pat. No. 5,424,565 A.

In the examples described in these publications layers of a second and first conductivity type are produced by doping on the main surfaces over a semiconductor body of a first conductivity type, preferably of n-type silicon. As a rule, the dopings are done by ion implantation or in some cases also by diffusion.

In a pn-diode (often also termed PIN diode), the simplest type of radiation detector, a semiconductor body of silicon with a very low n-type dopant concentration is redoped in the region of the one main surface by ion implantation into a p-type semiconductor and the n-type dopant increased in the region of the other main surface likewise by implantation.

By reverse biasing of the pn-diode a charge carrier-free zone, the so-called space charge region, is obtained, serving to detect the radiation. When electromagnetic or ionising radiation is absorbed in this layer, electron/hole pairs are generated therein by known ways and means, the quantity of which is proportional to the intensity or energy of the absorbed radiation. These are separated by the electric field and drift to the main surfaces where with the aid of suitable electrical amplification they can be used for detecting and analyzing the radiation. Basically also the other radiation detectors, as cited above by way of example, function by this principle.

One important characteristic of a radiation detector is the thickness of the radiation entrance window, or the semiconductor detector dead layer. To minimize absorption this layer needs to be as thin as possible. To attain this object the pn junctions in radiation detectors are configured as a rule strongly asymmetrical and abrupt. This is achieved either by metal/semiconductor junctions (Schottky barriers), by surface barrier layers or by doping with the aid of diffusion or ion implantation which has become the doping method of choice, since by varying the dosage and the energy of the dopant the doping profile can be varied within broad limits. As a rule, however, the doping profiles exhibit no narrow shape, they instead are showing a near Gaussian distribution of the dopants in the depth of the semiconductor body.

A further drawback of implantation doping is that it causes crystal damage which needs to be eliminated by subsequent temperature treatment. This, however, results in an additional undesirable diffusion of the profiles. These layers thus have the drawback that they cannot be made thin as one would prefer and that their effective thickness depends on the applied operating voltage of the detector and on the thermal annealing parameters. Indeed, a further change in the course of time may occur due to radiation effects.

Due to insufficient dopant concentration radiation entrance windows produced by implantation feature a high sheet resistance, making it necessary to further provide them with a metal electrode, e.g. of aluminum.

In addition to this, the still remaining crystal damages and metal impurities as may be included in implantation are a source of undesirable leakage currents which falsify the signals. All of these effects become particularly evident as drawbacks when detecting radiation which in silicon has only a very small range, such as e.g. UV light or low energy x-ray radiation in the energy range below 500 eV.

### SUMMARY OF THE INVENTION

A first aspect of the invention is directed to a method for fabricating a semiconductor radiation detector, comprising the steps of: providing a semiconductor body of a first conductivity type adapted to detect radiation, said semiconductor body having a first main surface and an opposite second main surface, and forming further semiconductor layers of a second conductivity type and the first conductivity type, respectively, on at least one of the first and second main surfaces of the semiconductor body, wherein at least one of the further semiconductor layers, functioning as a radiation entrance window, is formed as a highly-doped layer of the second conductivity type on the first main surface, and said layer being formed by epitaxy and doped in situ.

According to another aspect, a semiconductor radiation detector is provided, comprising: a semiconductor body of a first conductivity type for detecting radiation, said semiconductor body having a first main surface and an opposite second main surface, and further semiconductor layers of a second conductivity type and the first conductivity type, respectively, formed on at least one of the first and second main surfaces of the semiconductor body wherein at least one of the further semiconductor layers, functioning as a radiation entrance window, is formed as a highly-doped layer of the second conductivity type on the first main surface, and said layer being an epitaxial layer.

Other features are inherent in the methods and products disclosed or will become apparent to those skilled in the art from the following detailed description of embodiments and its accompanying drawings.

### BRIEF DESCRIPTION OF THE DRAWINGS

Embodiments of the invention will now be described, by way of example, and with reference to the accompanying drawings, in which:

FIG. 1a is a cross-section through a simple radiation detector with guard rings fabricated with the aid of ion implantation doping;

FIG. 1b is a cross-section through a first example embodiment (pn guard rings) of the method in accordance with the invention, comparable with that as shown in FIG. 1a, with layers of the second conductivity type on the first main surface and layers of the first conductivity type on the second main surface;

FIG. 2a is a cross-section through the rim of a simple radiation detector fabricated with the aid of ion implantation with a resistive layer of amorphous silicon in the peripheral rim for reduction of the electric field;.

FIG. 2b is a cross-section through a second example embodiment of the method in accordance with the invention, comparable with that as shown in FIG. 2a, but with an epi layer of the second conductivity type for reduction of the electric field;

FIG. 3a is a cross-section through the rim of a third example embodiment of the method in accordance with the invention as a radiation detector with resistive structures of the second conductivity type for reduction of the electric field;

FIG. 3b is a plan view on a fourth example embodiment of the method in accordance with the invention as a radiation detector with rectangular geometry with a schematic illustration of a resistive structures of the second conductivity type for reduction of the electric field in the rim;

FIG. 3c is a plan view on a fifth example embodiment as a radiation detector with round geometry with a schematic illustration of interconnected rings of the second conductivity type for reduction of the electric field in the rim;

FIG. 4a is a cross-section through a sixth example embodiment of the method in accordance with the invention as a silicon drift detector with a central electrode A (anode) of the first conductivity type on the first main surface, surrounded by concentric rings R1, R2, . . . Rn or a resistive spiral of the second conductivity type for generating the drift field with the guard ring structures w11, w12, . . . w1n of the second conductivity type in the rim for reduction of the electric field;

FIG. 4b is a cross-section through a seventh example embodiment of the method in accordance with the invention as a silicon drift detector as shown in FIG. 4a but with an additional epitaxial layer E1 of the first conductivity type in the region of the first main surface;

FIG. 5a is a cross-section through an eighth example embodiment of the method in accordance with the invention as a silicon drift detector with a central electrode A (anode) of the first conductivity type on the first main surface, surrounded by a resistive layer ws1 of the second conductivity type for generating the drift field with the guard ring structures w11, w12, . . . w1nof the second conductivity type in the rim for reduction of the electric field, as well as with a layer pol of the second conductivity type on the second main surface;

FIG. 5b is a cross-section through a ninth example embodiment of the method in accordance with the invention as a silicon drift detector as shown in FIG. 5a but with punctiform Me 21 central and ring-shaped outer Me22 contacting of the layer of the second conductivity type on the second main surface for generating a voltage gradient;

FIG. 6 is a cross-section through a tenth example embodiment of the method in accordance with the invention as a silicon drift detector with a resistive layer ws1 of the second conductivity type on the first main surface, surrounded by a ring A of the first conductivity type, a central contact Me11 to the resistive layer and an outer ring-shaped contact Me12 of the resistive layer, as well as with an epi layer p02 (E2) of the second conductivity type on the second main surface;

FIG. 7a is a cross-section through an eleventh example embodiment of the method in accordance with the invention with an epi layer El of the first conductivity type and E2 of the second conductivity type on the first main surface of a semiconductor body and with zones B1, B2, . . . Bn of additional doping of the second (or first) conductivity type in the epi layer E2 of the second conductivity type;

FIG. 7b is a cross-section through a twelfth example embodiment of the method in accordance with the invention with an epi layer of the first conductivity type (E1) and second conductivity type (E2) on the first main surface of a semiconductor body and locally deposited additional layers of the second conductivity type B1, B2, . . . Bn; and

FIG. 7c is a cross-section through a thirteenth example embodiment of the method in accordance with the invention with an epi layer of the first conductivity type (E1) and second conductivity type (E2) on the first main surface of a semiconductor body and locally deposited additional layers of the first conductivity type B1, B2, . . . Bn.

### DESCRIPTION OF THE PREFERRED EMBODIMENTS

Like elements are identified by like reference numerals in the following figures to avoid repeat descriptions -of the elements already described in discussing the individual figures.

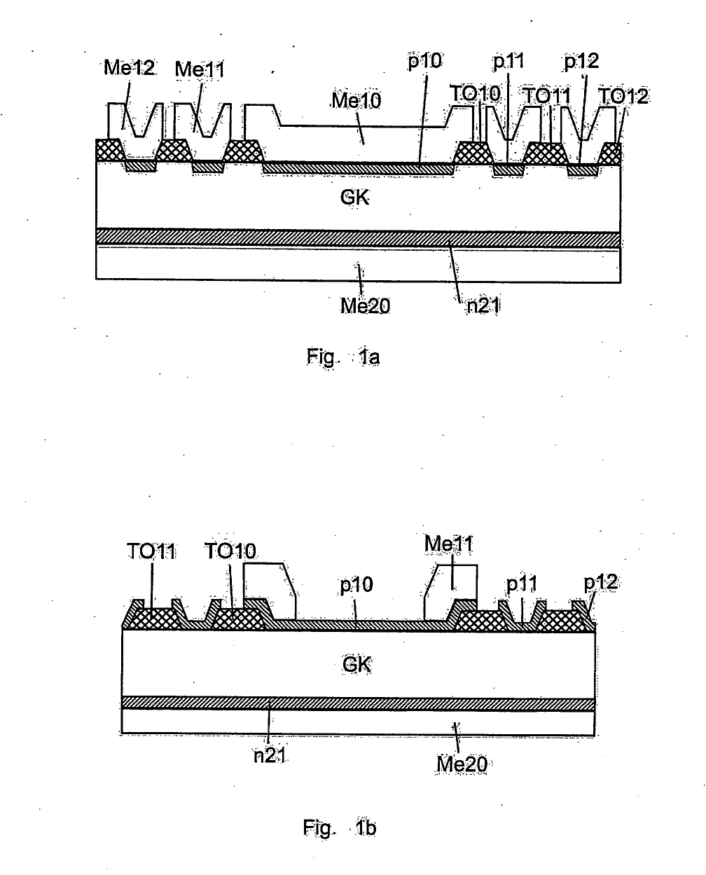

Before proceeding further with the detailed description of FIG. 1, however, a few items of the embodiments will be discussed.

In accordance with the embodiments of the invention it has now been discovered that by applying epitaxy instead of ion implantation for forming the further semiconductor layers of at least one of the second and the first conductivity type on the semiconductor body, all of the above-mentioend drawbacks can be avoided.

With the aid of a method according to an embodiment it is now possible to vary the layer thickness and dopant concentration within broad limits. There is no problem technically in generating with the aid of suitable epitaxy methods sharp doping profiles, indeed even so-called delta layers. Since doping concentrations up to 10E21 per cm are now possible, there is no problem in producing extremely thin abrupt layers of the second or first conductivity type in the thickness range of a few nanometers (nm) on a semiconductor body of the first conductivity type.

The epitaxial layers (hereinafter “epi layers”) still feature a sufficiently high conductivity so that there is no need for a metal electrode, they thus being suitable in accordance with the invention particularly to advantage as entrance windows for short-range radiation. They are superior to thin layers produced by implantation not only by being less thick but also by an optionally variable doping profile which, as a rule, is configured homogenously, resulting in these epi layers also featuring added radiation hardness and long-term stability.

In accordance with the embodiments of the invention, definedly doping the epi layer as achieved in the entrance window is particularly of advantage for the x-ray detectors since the low energy x-ray spectrum is highly influenced by the thickness and doping of the entrance window. When low energy x-ray radiation passes through the entrance window it is known to be partly absorbed, resulting in the number of x-ray quanta detected being less than their primary number. However, electrons generated in the dead layer on absorption of an x-ray quantum gain access to the detector and falsify the spectrum.

The shape of spectrum is influenced even more by electrons which are generated on absorption of radiation just below the window in the detector, but which leave the detector through the window because of their energy (a few eV). By incorporating a potential barrier in the entrance window these electrons can be reflected back into the detector.

In accordance with an embodiment achieving such a potential barrier is also possible by defined doping the epi layer in the entrance window. This is done by depositing on an n-type bulk firstly an n-type epi layer with elevated n-doping and then on top thereof a very thin epi layer with very high p-doping. The thickness and doping of the n-doped epi layer are selected (e.g. a hundred times higher than the bulk doping) so that a voltage drop of a few volts occurs across this pn junction in the epi layer, so that the electrons first need to overcome this potential barrier to escape from the detector.

Another possibility of configuring a potential barrier is to deposit or grow a thin layer of a dielectric, preferably a thermal oxide, on the epi layer of the entrance window. In this case, the doping of the epi layer can be homogenous since the thickness of the potential barrier is determined by the work function of the electrons or holes for silicon and the dielectric (approx. 3.2 eV for silicon oxide on silicon).

Since the epitaxial layers can be grown on the bulk practically free of defects they, unlike implanted layers, show fewer crystal defects, which are able to act as generaton/recombination centers for charge carriers. This is why detectors fabricated by the method in accordance with the invention are characterized by lower leakage currents and better spectroscopic properties.

A further advantage of the method in accordance with an embodiment is that the epitaxial layer of the second conductivity type can be simultaneously used to reduce the electric fields in the rim of the detector. This is achievable, as is known, either by guard rings or even simpler by a resistive layer on the passivating oxide. In known types of radiation detectors the guard rings are likewise fabricated by ion implantation. For fabricating the resistive layers on the oxide, either amorphous silicon or polysilicon finds application. For this purpose, however, an additional step in the process is needed. Accordingly, the method in accordance with the invention is characterized by fewer technical steps being needed.

Particularly of advantage in the method in accordance with an embodiment is the application of selective epitaxy, because then patterning the epi layer is eliminated by the epi silicon being deposited only on the silicon areas etched free of oxide.

Further embodiments in accordance with the invention read from the dependent claims, particularly of interest being the application in the fabrication of complex devices such as SDDs and CCDs and pixel detectors as well as for devices having integrated electronic components.

A method in accordance with an embodiment of the invention will now be described, without restricting its scope, by way of example aspects—in which high-purity n-type silicon preferably with the orientation (100) is selected as the bulk—with reference to the drawings.

Referring now to FIG. 1a there is illustrated a cross-section through a simple pn-diode or pin diode. The detector is fabricated by the known method of ion implantation. It has a bulk GK of the first conductivity type with n-type doping. Provided on the first main surface are zones of the second conductivity type p10, p11, p12 . . . p1n produced by ion implantation. These are separated from each other by isolating thermal oxide TO. Deposited on the layers are metal electrodes Me of aluminum.

Provided on the second main surface is a thin highly doped layer of the first conductivity type n21 produced by ion implantation, covered again by a metal electrode Me20 of aluminum.

The central region of the second conductivity type p10 on the first main surface simultaneously serves as a entrance window for of the radiation and for generating the charge carrier free space charg region when biased in reverse. This central region is surrounded by ring-shaped zones of the second conductivity type p11, p12 . . . p1n which serve as guard rings and decrease the electric field to the exterior.

Referring now to FIG. 1b there is illustrated a cross-section through a comparable pn-diode but which has been fabricated by the method in accordance with the invention, The layers of the second conductivity type p10 to p1n on the first main surface and those of the first conductivity type n21 on the second main surface are deposited by epitaxy, preferably selective epitaxy.

Unlike FIG. 1a only one metal electrode Me11 is provided on the first main surface in the form of a ring shaped bond pad needed to enable the electrical connections to the electronic components. The bond pad is preferably of TiN and aluminum, the TiN serving as a barrier layer, to avoid the Al alloying with the silicon of the epi layer.

Just the same as in ion implantation the radiation entrance window p10 and the guard rings p11 to p1n can be fabricated simultaneously in the epitaxial application.

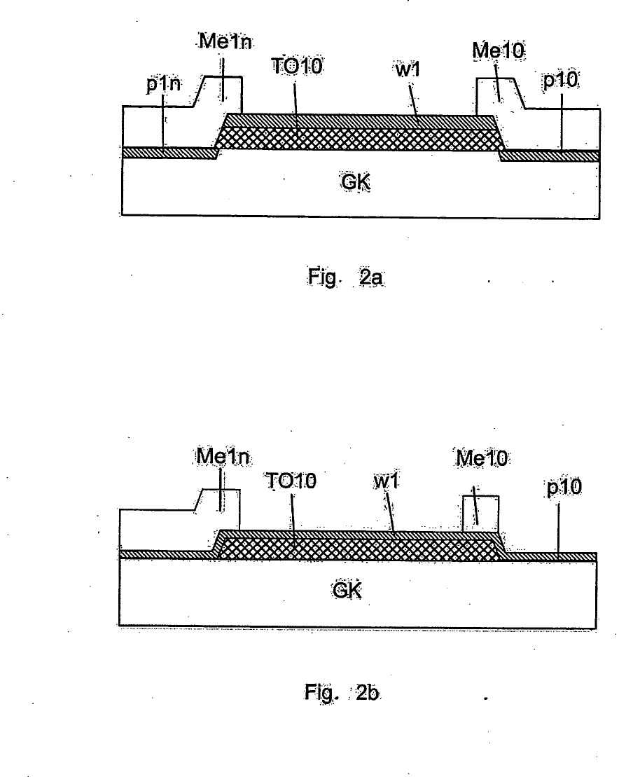

Referring now to FIG. 2a there is illustrated a section through the rim of a simple pn-diode fabricated by ion implantation in which, however, reduction of the voltage is achieved with the aid of a resistive layer w1 such as e.g. polysilicon or amorphous silicon. The resistive layer w1 can be applied over the full surface area, or patterned in the form of a spiral or in the form of interconnected rings w11 to w1n. Where a full surface area resistive layer is applied the desired-profile of the resistance to the edge can also be set by etching away zones differing in size. The resistive layer is electrically connected on the one side to the entrance window p10 and at the other end pin to the bulk GK.

Ideally, outer bonding the resistive layer w1 to the bulk GK should be made via contact of the same conductivity type as that of the bulk. To avoid this, however, this contact can be simultaneously used as the separation line of the semiconductor chip, since during cutting the rectifying behavior of a contact of the second conductivity type is destroyed, resulting in an ohmic shortcut to the bulk.

Referring now to FIG. 2b there is illustrated the cross-section through a similarly structured pn-diode in which, however, the resistive layer w1 consists of the same epi layer as the entrance window p10 simultaneously deposited therewith.

The method in accordance with the invention thus requires no additional deposition of the resistive layer and thus requires at least one mask step less for patterning.

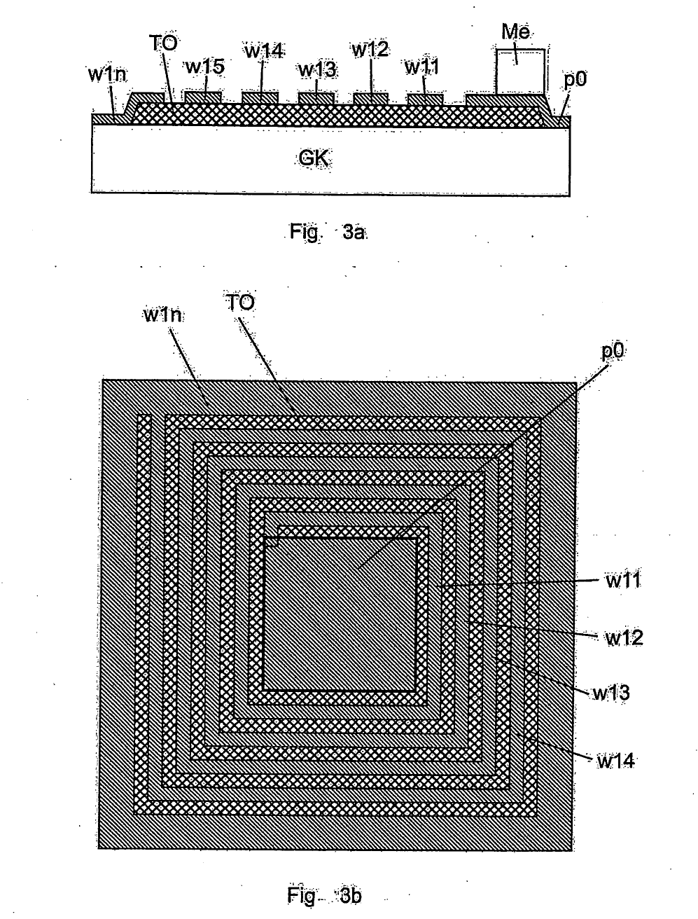

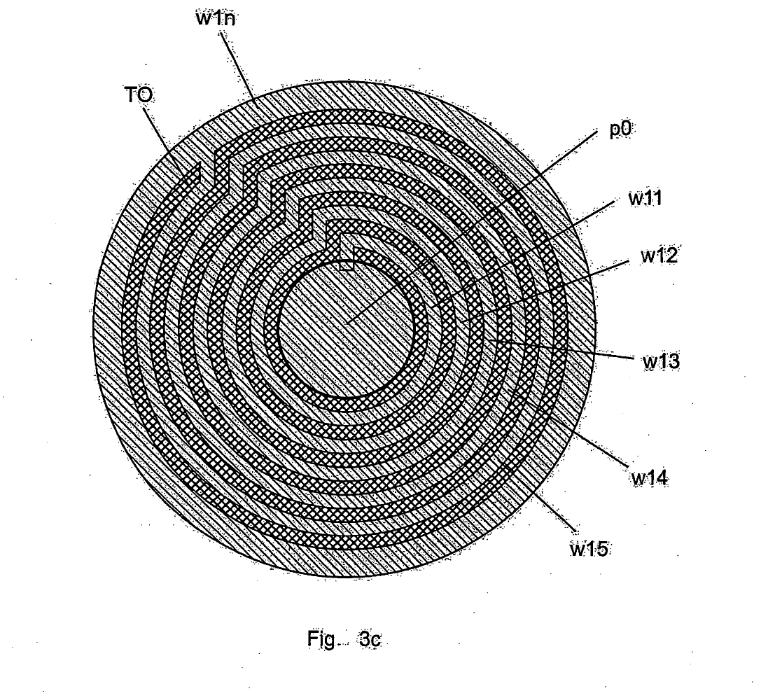

Referring now to FIG. 3a there is illustrated the cross-section through a detector whose resistive layer is fabricated in the rim by the method in accordance with the invention as spirals w11, w12, . . . w1n or as an interconnected ring pattern w11, w12, . . . w1n.

Referring now to FIG. 3b there is illustrated schematically the plan view of a rectangular detector having a spiral pattern w11, w12, . . . w1n of the resistive layer in the rim area.

Referring now to FIG. 3c there is illustrated a round pattern of interconnected rings w11, w12, . . . w1n as the resistive layer, the outer contact w1n again being located on the separation line.

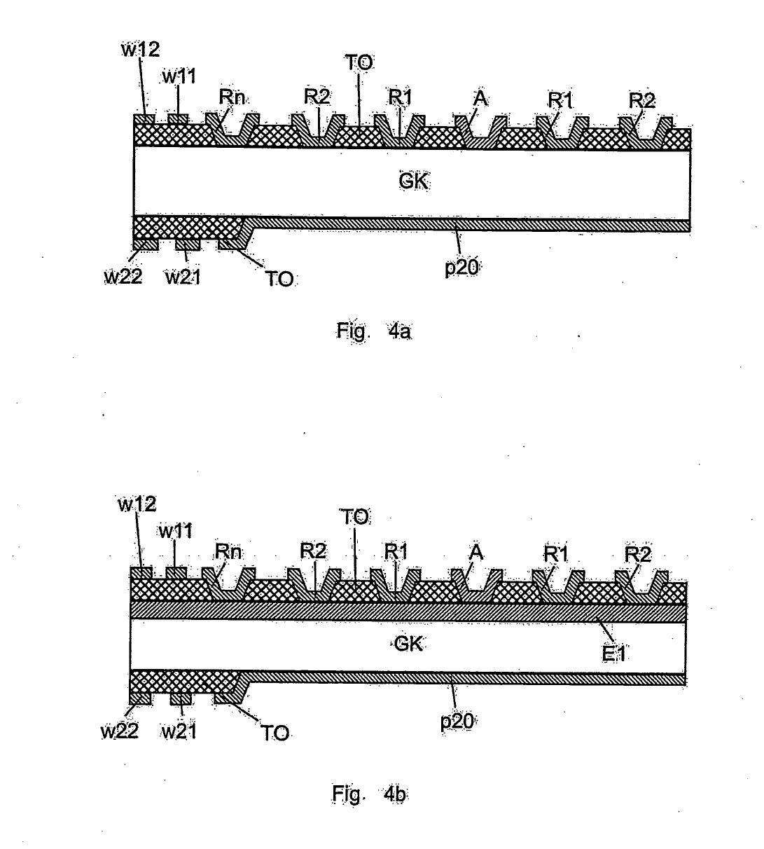

Referring now to FIG. 4a there is illustrated as a third example embodiment a known SDD in which all zones of the second and first conductivity type in the region of the two main surfaces are fabricated by epitaxy, preferably by selective epitaxy. The drift voltage needed for SDDs can be generated as known by drift rings R1, R2, . . . Rn or by a spiral R1, R2, . . . Rn or to advantage and in accordance with the invention by rings which are interuppted and interconnected similarly to the pattern as shown in FIG. 3c. To drain off the electrons below the oxide TO a joined ring pattern (not shown) of epi silicon on the oxide is likewise suitable. This can be fabricated in a single step simultaneously with the drift rings R1, R2, . . . Rn. As described in the third example embodiment the epi layer can also be used for reduction of the voltage in the rim (w11, w12, . . . w1n).

Located at the center of the first main surface is an anode A in the same conductivity type as the bulk for connecting the bulk and serving to collect the majority charge carriers generated by the radiation. The anode may be likewise fabricated of epi silicon and is covered with a metal bond pad, preferably of TiN and aluminum.

Serving to drain off the electrons from the anode is an integrated diode (not shown in the drawing) or a high-impedance connection to the bulk, preferably made of epi silicon or fabricated by ion implantation. It is particularly of advantage to connect the anode via this resistance to the same electrode serving to drain off the electrons below the oxide.

At the radiation entry side this example embodiment of an SDD with epi layers comprises a simple pn-diode p20 with patterned guard structures w21, w22, . . . w2nfor voltage reduction as already described.

The salient advantages of SDDs fabricated by the method in accordance with the invention is that the radiation entrance windows p20 can now be made extremely thin, e.g. 5 to 30 nm, and highly homogenously and doped within a broad range and radiation hard. Because the interface between the epi layer and the bulk being clean and substantially defect-free the leakage current contribution of this region is negligible.

Since the epi layer can be fabricated with a defined layer resistance it is possible, instead of dividing the voltage by concentric drift rings to use a spiral pattern or simply open rings connected at both ends with the two neighboring rings similar to the arrangement as shown in FIG. 3c. The resulting voltage divider is insensitive to radiation and thus has long-term stability.

Another advantage afforded by the method in accordance with the invention is that, here too, the same as with simple pn-diodes, the high field strengths at the rim of the detector can be reduced via suitable configured resistive patterns of epi silicon fabricated in a single deposition process together with the entrance window and the drift structures respectively. Here also preference is given to open ring patterns with connections to neighboring rings which may be configured as pn structures or simply deposited on the passivating oxide layer.

Referring now to FIG. 4b there is illustrated an example embodiment of a drift detector similarly structured as shown in FIG. 4a except that this device features on the first main surface an additional epi layer E1 a few micrometers thick, the enhanced doping of which is of the same conductivity type as that of the bulk. One advantage of this embodiment is that the reverse voltage applied to the radiation entry side to deplete the bulk features a high tolerance. Due to the enhanced doping under the drift rings local punchthrough caused by inhomogenous doping of the bulk is reduced. An SDD of this embodiment is insensitive to changes in voltage and is more stable in practical operation.

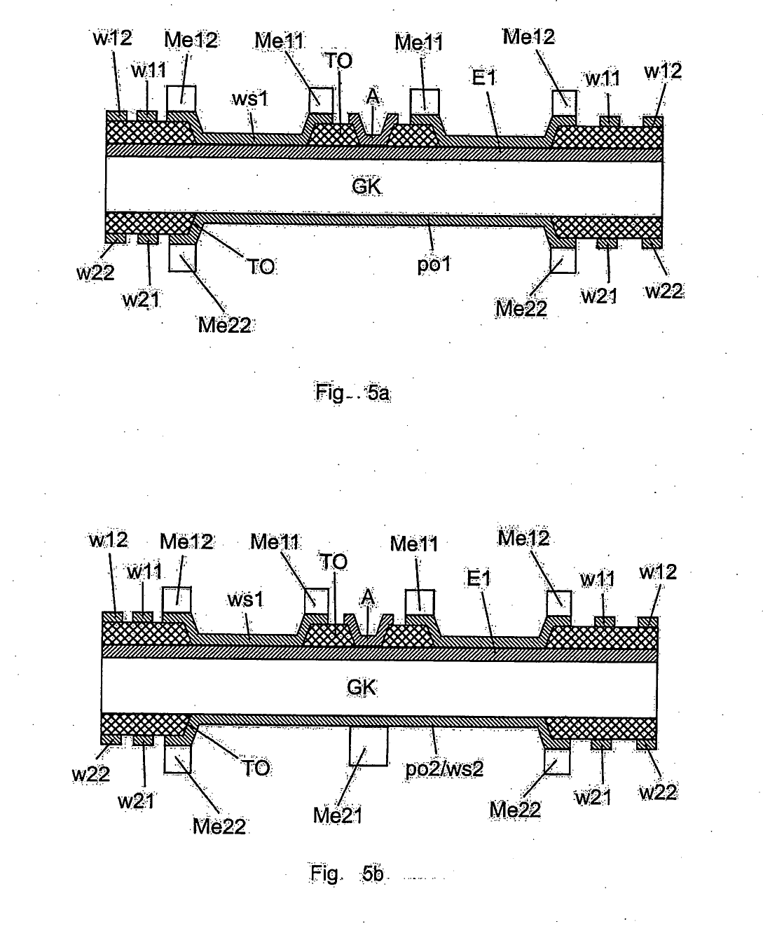

Referring now to FIG. 5a there is illustrated an example embodiment of a drift detector comprising a central anode A of the first conductivity type on the first main surface, surrounded by a epitaxial resistive layer ws1 of the second conductivity type with an inner contact ring Me11 and an outer contact ring Me12 for generating the drift field.

One special advantage afforded by this arrangement is that oxide layers no longer exist on the first main surface in the region of the drift field, it being known that charge carriers are generated under the oxide which contribute to noise if not totally drained off. Another drawback of oxides is their sensitivity to radiation and the associated increase in density of the interface states. Both effects can contribute towards a degradation in the properties of SDDs during their operation, particularly when for generating the drift field concentric rings are used which employ the punchthrough effect to reduce the voltage.

Referring now to FIG. 5b there is illustrated the identical structure of a further example embodiment in which, however, the epi layer po2 or ws2 of the second conductivity type is connected on the second main surface to a central electrode Me21 and a contact ring Me22 in the outer region and is likewise used as a voltage divider.

Closed sheet resistive layers of epi silicon can always be put to use to advantage for generating the drift field when the drift zones are linear. In a circular arrangement of the drift rings the resistance changes with the radius and the electric field in the rim area becomes very weak, resulting in the charge moving slower in the rim than in the center. Since the surface area of the detector increases squared with the radius, the majority of the radiation impacts the rim area and thus has a longer path to cover. This can be improved by the interchage the potential relationships as explained in the following.

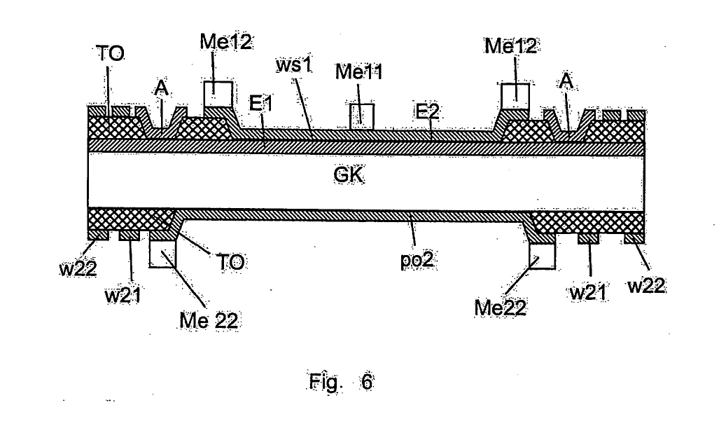

Referring now to FIG. 6 there is illustrated the cross-section through an example embodiment of a SDD in which deposited on the first main surface is an epi layer E2 (ws1) of the second conductivity type comprising a central point contact Me11 and a ring-shaped peripheral contact Me12. Provided in the outer rim is a ring-shaped anode A of the first conductivity type. This device is operated so that the drift field is oriented outwardly and the majority charge carriers are collected on the ring-shaped anode A.

This embodiment of an SDD has the advantage of a better charge collection, but has the drawback of a higher anode capacitance and thus associated therewith higher electronic noise. However, in addition to those as already described there are a few further advantages. The electrode with the highest voltage is in the center and not on the edge of the device, i.e. no guard structures being needed to reduce the voltage in the outer region. This mode of operation is particularly of advantage in arrays since no high fields need to be reduced in the interface of the individual cells. Indeed, the outer anode can be used in common for some or all cells to thus avoid the undesirable charge loss in the rim area of SDDs. Such SDDs find useful application where the requirements on the spectroscopic properties are not very high but the mechanical structure needs to be simple and rugged, such as e.g. in the combinaion with scintillators in medical applications.

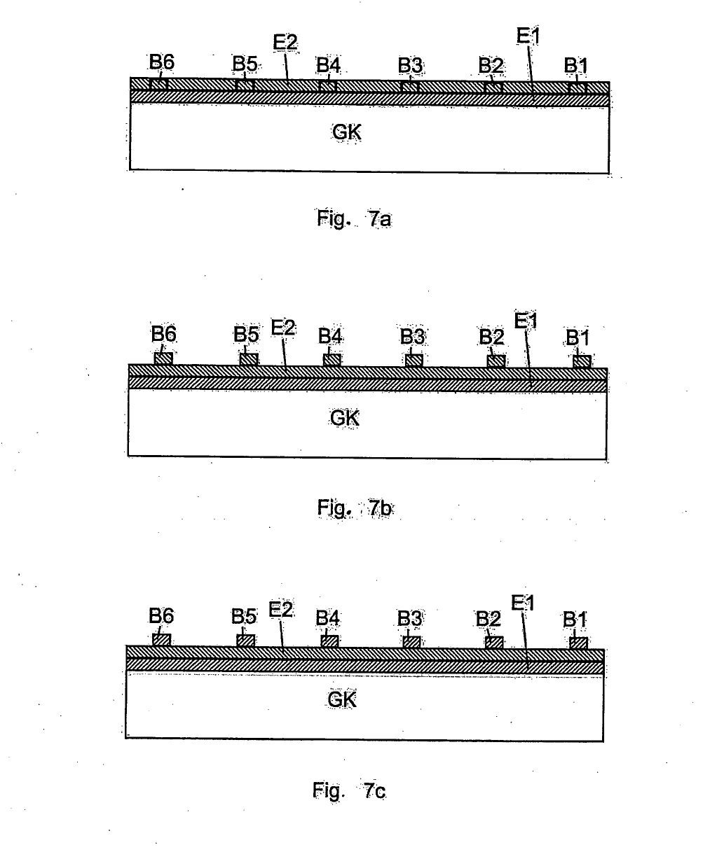

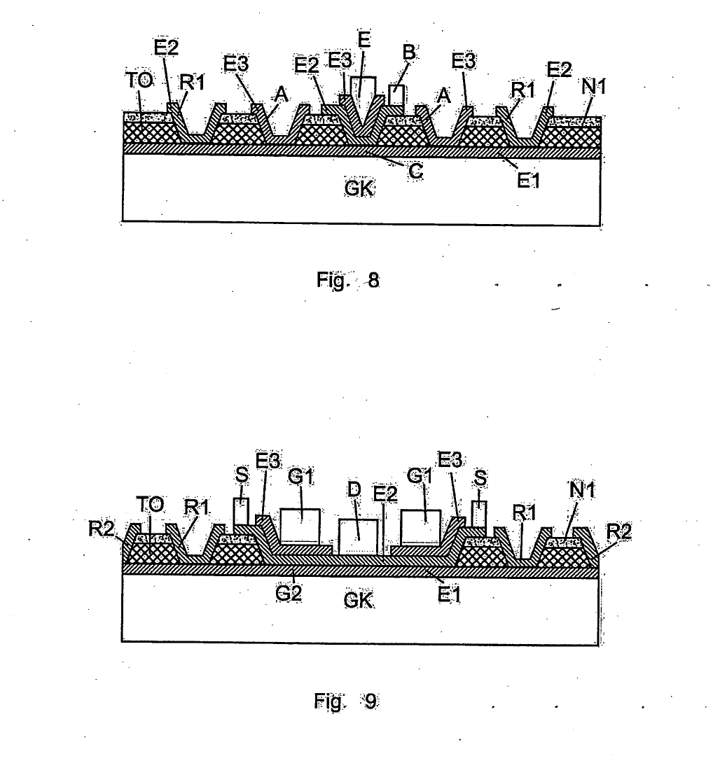

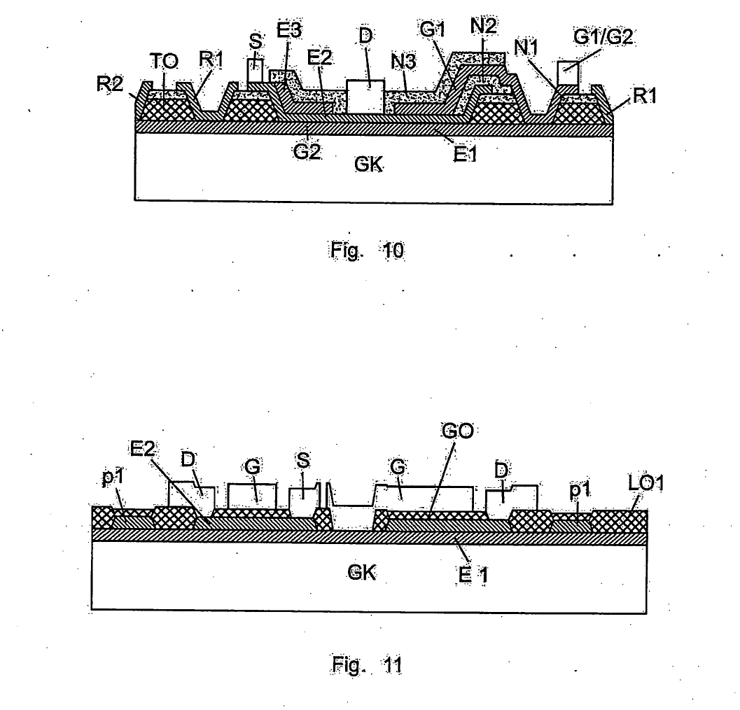

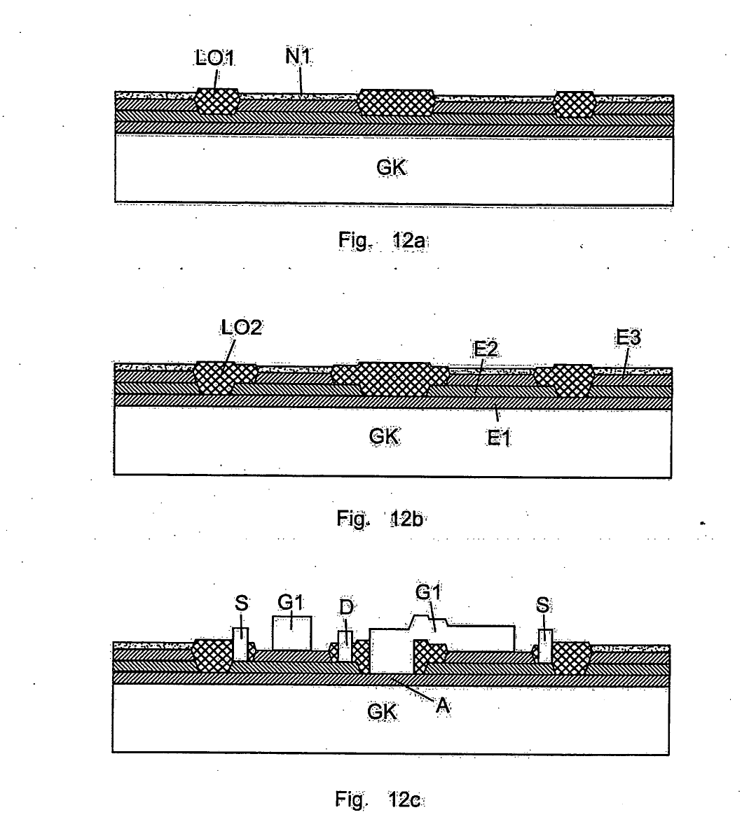

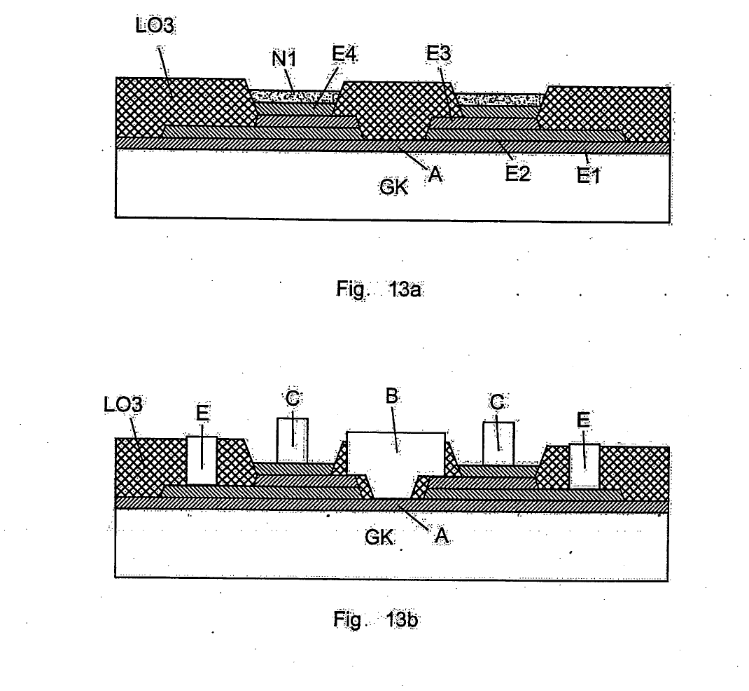

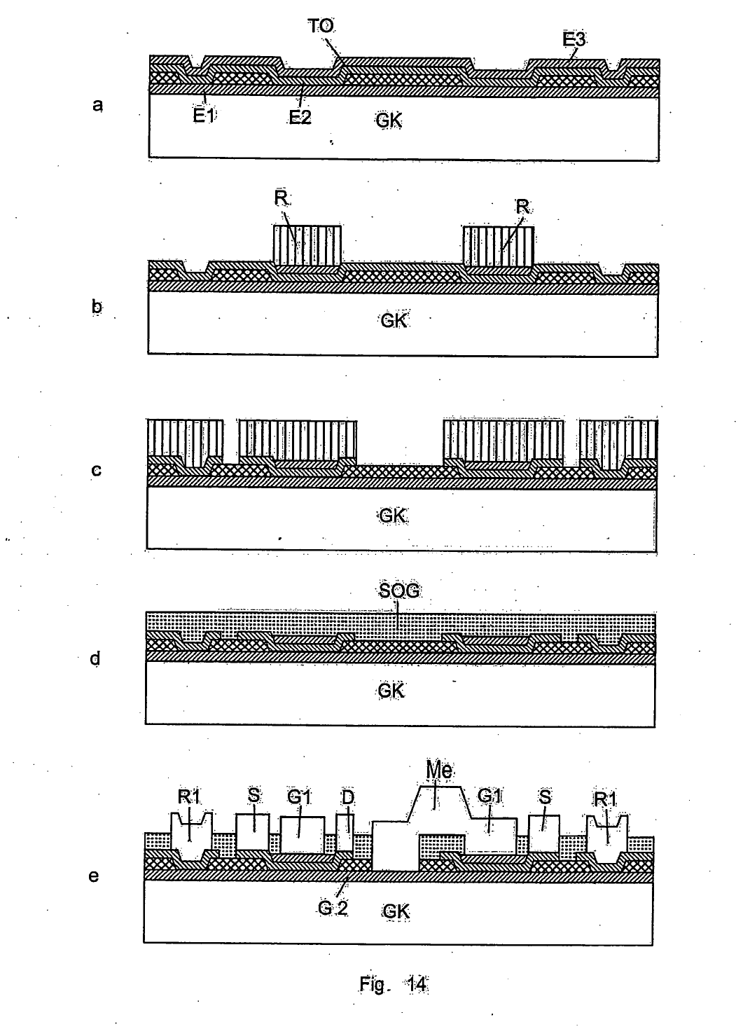

Referring now to FIGS. 7a to 7c there are illustrated examples of how the conductivity of the epi layer E2 of the second conductivity type can be decreased to e.g. overcome the drawbacks as described above. As evident from FIG. 7a localized doping B1, B2, . . . Bn is provided by ion implantation, FIG. 7b showing a further highly doped epi layer and FIG. 7c an epi layer of the opposite conductivity type. The layer resistance is varied by suitably patterning the epi layers as shown in FIGS. 7b and 7c in the zones B1, B2, . . . Bn where the additional epi layer remains. State of the art dry or wet chemical or electrochemical etching methods can be employed for patterning. It is particularly simple to pattern n-type epi on a highly doped p-type layer of silicon since KOH can be used for etching which etches n-type silicon at a higher rate than p-type silicon, a highly doped layer of p-type silicon thus constituting an etch stop.

Particularly of advantage for patterning the epitaxial zones is the application of selective epitaxy. In this method, which is well suited for thin epi layers, epitaxial silicon is deposited only on exposed silicon and not on the oxide in thus saving the need of a mask for patterning the epi layer.

Applying epitaxial layer deposition for the fabrication of radiation detectors is also excellently suitable for integrating various electronic components on the detectors, such as, for example, resistors, capacitors, conducting paths, diodes, MOSFETs, JFETs and bipolar transistors.

The known SDDs comprising an integrated first JFET make use exclusively of ion implantation to generate doping layers needed for a JFET. This is why, as is known, they suffer from a series of drawbacks both in the fabrication process and in their properties, the most serious of which are cited in the following:

high implantation energies with heavy broadening of the doping profiles,

uncertainties in dopings resulting in heavy dispersion of the transistor parameters, residual radiation damage and impurities during implantation, all of which are the cause for increased noise in the transistors,

poor transconductance of transistors,

several implantation steps including the photo techniques necessary therefor,

installing the transistor in the detector instead of on the detector, resulting in reduced sensitivity of the detector in the transistor range, and

high failure rate and high production costs.

Most of these drawbacks are eliminated in accordance with an embodiment when fabricating the layers as needed in the production of electronic devices with the aid of epitaxy. Indeed, the production process can even be simplified in many cases whilst enhancing stability and quality of the devices and increasing the yield and reliability with a considerable reduction in the costs.

To limit the great many of different embodiments possible, all SDD types are configured in the following so that they comprise on the first main surface an additional higher doped epi layer E1 of the same conductivity type as the bulk. This is not a restriction but a particularly advantageous SDD embodiment in accordance with the invention with integrated electronic components.

The method in accordance with the invention for fabrication of radiation detectors, particularly of SDDs with integrated electronic components with application of epitaxy will now be explained by way of various example embodiments. For this purpose the structure of JFETs, bipolar-transistors and a MOSFET is shown in the following FIGS., by way of example, as can be integrated to advantage in the anode region of SDDs.

In the first method of fabrication in accordance with the embodiment as described the epi layers are applied and patterned in sequence unlike the second method of fabrication in accordance with the invention as later explained in which firstly most or all epi layers are deposited in one working step and patterning is done thereafter.

It is, of course, also possible to combine these two methods with selective epitaxy as may prove particularly of advantage in special cases.

The first method in accordance with the invention will now be detained by way of three example embodiments with reference to the drawings in which:

FIG. 8 is a cross-section through an npn bipolar transistor fabricated by the method in accordance with the invention;

FIG. 9 is a cross-section through a JFET of ring-shaped design fabricated by the method in accordance with the invention; and

FIG. 10 is a cross-section through a JFET of ring-shaped design with connected gates G1 and G2 fabricated by the method in accordance with the invention.

Referring now to FIG. 8 there is illustrated a schematic cross-section through an npn bipolar transistor as may be integrated as a reset element in the anode region of SDDs. The full-length epi layer E1 of the first conductivity type on the first main surface serving as the anode for the majority charge carriers simultaneously forms the collector of the transistor. This is topped by the layers E2 and E3 for the base and emitter fabricated with the aid of epitaxy.

Referring now to FIG. 9 there is illustrated the structure of a circular JFET as may also be integrated in the anode region of SDDs. In this arrangement the anode of the first conductivity type serves as the inner gate G2 of the transistor, covered by an epi layer E2 of the second conductivity type deposited thereon as a channel, covered in turn by a further epi layer E2 of the first conductivity type as the outer gate G1. The transistor is controlled by the charge incoming in the inner gate G2.

This JFET can also be employed in accordance with the invention as a reset element, the layer sequence G1, S, G2 representing namely a parasitc npn bipolar transistor. Applying a positive voltage pulse to G1 permits neutralizing or draining off the electron charge on G2.

Referring now to FIG. 10 there is illustrated a further embodiment of the JFET as shown in FIG. 9. In this example embodiment inner and outer gate are interconnected. The sequence in the fabrication method is the same as that for the npn bipolar transistor as shown in FIG. 8.

In fabrication of the example embodiments of detectors and transistors as described, the first method of fabrication is applied with successive deposition and patterning of the individual epi layers. There are a great many wet and dry chemical patterning methods available technically for achieving a variety of step sequences which as prior art do not need to be discussed in detail herein. These can be combined, where necessary, with the technique of selective epitaxy to special advantage.

This is why in the following the layer structure of the transistors as shown in FIG. 8 and FIG. 9 is described with a very simple technical method in which oxide, nitride and epitaxial layers are patterned by wet chemical means making use of merely buffered hydrofluoric acid and phosphoric acid as the etch solutions.

The step sequence in fabricating the npn transistor as shown in FIG. 8 is as follows:

In the first step an epi layer E1 having the same conductivity type as the n-type semiconductor body but higher doped is deposited thereon.

In the second step the silicon wafer is thermally oxydized (TO).

In the third step a layer of silicon nitride N1 is deposited.

In the fourth step the layer of silicon nitride is patterned and removed in the areas where later the p-type epi layers are to be desposited.

In the fifth step the oxide is etched away at open locations.

In the sixth step the p-type epi layer E2 is deposited.

In the seventh step again a layer of silicon nitride N2 is deposited.

In the eighth step the second layer of nitride N2 is patterned and opened at all locations where the epi layer E2 is to be removed.

In the ninth step the epi layer E2 is etched off locally.

In the tenth step the anode A and emitter E regions are opened in the layer of nitride N2.

In the eleventh step the anode region A is opened in the oxide OT.

In the twelfth step n-type epi silicon E3 is deposited.

In the thirteenth step a third layer of nitride N3 is deposited.

In the fourteenth step the nitride layer N3 is patterned.

In the fifteenth step the n-type epi layer E3 is patterned, and anode region A and emitter E defined.

In the sixteenth step metallization is performed.

In the seventeenth step the metal layer is patterned.

In accordance with a further embodiment, JFET fabrication is accomplished similarly. Although the first method in accordance with the invention can be implemented with few technological complications it has many drawbacks, one of which is multiple deposition of silicon nitride as the etch mask for the epi layers. Another is the risk of contamination when patterning the individual layer sequences, and also the necessity of cleaning before each epitaxy process. Likewise a drawback is the resulting three-dimensional topography which causes fractures at sharp edges.

Some of these drawbacks of the first method can be eliminated by application of selective epitaxy as well as dry etching or selective wet chemical processes, all of which are not discussed herein because as prior art they are familiar to the person skilled in the art and are simply variations on the fundamental idea of the invention.

Of greater advantage is, however, a second method in accordance with the invention in which all or the majority of the epi layers are deposited in a single working process in sequence without the silicon wafers having to be removed from the epi reactor in-between.

One major advantage afforded by the second method in accordance with the invention is that the interfaces between the individual epi layers exhibit no additional contaminations or crystal defects whatsoever, because the sequence of layers is produced in a single operation. Changing the conductivity type is known to be achievable very simply by changing over to the corresponding doping source.

The task now is to accurately defined insulate, structure and connect each of the superposed layers E1, E2, E3, E4 etc to create the desired detector structures and electronic components.

This task is achieved in accordance with the invention by application of known methods of selective epitaxy, the local oxidation (LOCOS) technique, wet chemical and dry isotropic and anisotropic as well as selective etch techniques, and including anodic oxidation or anodic etching.

By way of a few further embodiments these techniques or combinations thereof will now be explained, here again, merely by way of example and in now way intended to cover all of the many and varied possibilities of combination.

The method in accordance with further embodiments of the invention will now be further detained by way of example with reference to the drawings in which:

FIG. 11 is a cross-section through a MOSFET with two epi layers E1 and E2 fabricated by the method in accordance with the invention;

FIG. 12 is a cross-section through a circular JFET with connected gates on three epi layers E1, E2 and E3 fabricated by the method in accordance with the invention; and

FIG. 13 is a cross-section through a pnp bipolar transistor on four epi layers E1, E2, E3 and E4 fabricated by the method in accordance with the invention.

Simultaneously fabricated with these devices are the desired radiation detectors, preferably SDDs.

Referring now to FIG. 11 there is illustrated the cross-section through a schematic illustrated MOSFET as can be fabricated by application of the LOCOS technique on a sequence of p-type epi E2 and n-type epi E1 layers. By local oxidation LO of the topmost epi layer E2 it is possible, on the one hand, to insulate the transistor area from the drift rings pi (fabricated at the same time), on the other, to produce an insulating layer to the lower n-type epi layer E1. After gate oxidation GO this is patterned and the contact holes to the drain D, source S and anode A are opened. Finally in a metallization step the anode A is connected to the gate G.

Simultaneously in fabrication of the transistor the drift rings p1, p2, . . . pn are produced and the necessary contacts provided.

Referring now to FIG. 12 there is illustrated a JFET fabricated in accordance with the invention in utilizing three epi layers E1, E2 and E3 with twice application of the LOCOS technique. This JFET is excellently suitable as an amplifier element for SDDs, CCDs and pixel detectors.

The main steps in this method of fabrication will now be explained with reference to FIGS. 12a to 12c. Referring now to FIG. 12a there is illustrated the stack of three epi layers after the first local oxidation LO1. Because of the deposited layer of silicon nitride N1 oxidation is only possible where the surface is free of nitride. These areas are intended later to insulate the transistor from the drift rings and for contacting the anode respectively.

Referring now to FIG. 12b there is illustrated how contact holes can now be opened to the various areas and finally the drain D, source A and gate G zones provided with metal electrodes, In this example embodiment the anode A is connected to the gate G.

Referring now to FIG. 13 there is illustrated greatly abbreviated a pnp bipolar transistor comprising a sequence of four epi layers E1, E2, E3 and E4 fabricated with triple application of the LOCOS technique. This transistor in accordance with the invention can be integrated to advantage in the anode zone of SDDs.

Referring now to FIG. 13a there is illustrated the situaton after triple local oxidation LO3 reminiscent of the method as already explained by way of the example of the JFET as shown in FIG. 12, whilst FIG. 13b shows the contacting paths after opening of the contact holes and metallization. In this pnp bipolar transistor the anode A is connected to the base B and is thus suitable for signal amplification in SDDs, CCDs and pixel detectors.

For a better understanding the LOCOS technique was cited in the last three examples for patterning and insulating the transistors. Contrary to the classic LOCOS technique in which thermal oxidation is performed, in these cases an anodic oxidation is of greater advantage because it can be implemented at room temperature. In application of thermal oxidation there is a risk that the abrupt doping profiles of the individual epi layers are blurred by diffusion. Where necessary, this can be maintained within reasonable limits by wet oxidation at low temperatures or by high-pressure oxidation, but represents nevertheless a disadvantage as regards the quality of the devices.

In combination of the LOCOS technique with selective, isotropic and anisotropic dry and wet chemical etches the method in accordance with the invention can thus be adapted to the technological circumstances, it, for instance, being known to etch away n-type silicon selectively over highly doped p-type silicon with KOH since the etching action automatically stops as soon as the p-type silicon is reached. Electrochemical etching is also excellently suitable for removing layers of a certain conductivity type definedly, it being possible to both oxidize and etch electrochemically when using suitable electrolytes.

As regards the quality of the devices all methods which avoid high temperatures are superior to high temperature methods and thus used to advantage. A last example embodiment which combines to advantage thermal oxidation, selective etching with KOH and electrochemical etching will now be described with reference to FIG. 14.

Referring now to FIG. 14 there is illustrated a drift detector and circular JFET fabricated by the method in accordance with the invention with connected gates G1 and G2, the salient steps for the JFET of which are evident.

In FIG. 14 the salient steps of a particularly soft, combined method of fabricating SDDs with an integrated circular JFET are illustrated a to e, starting from in this case a wafer of n-type silicon already provided with a lower ohmic n-type epi layer El.

The wafer is thermally oxidized (TO) and passivated on the second main surface with a suitable protective layer (e.g. photoresist). The first main surface on which the drift structures and the integrated transistor are to be fabricated is first photolithographically patterned and the oxide TO etched away at all locations where contacts to the n-type epi layer E1 of the bulk need to be produced. These are the drift rings R1, R2, . . . Rn, a contact (not shown) for draining off the electrons under the oxide in the;drift zone, the guard ring structure (not shown) as well as the later channel area of the JFET.

In the next step p-type epi silicon E2 and n-type epi silicon E3 are deposited in a single process as evident from FIG. 14a. Then, by selective etching with KOH the n-type epi layer E3 is removed at all locations, except in the gate zone G of the JFET or in the rim area of the detector, to likewise integrate electronic components there. After this, the wafer is coated with photoresist R and the zones exposed in which the p-type epi layer E2 is to be removed. This is the condition as shown in FIG. 14b in defining the drift and guard rings (not shown) and particularly also the transistor regions and the later connections to the n-type epi layer of the bulk.

Next, the p-type epi silicon E2 is removed electrochemically at all open locations in thereby patterning drift rings and guard rings. At the center of the transistor the p-type epi silicon E2 is likewise etched away as evident from FIG. 4c, after which passivation e.g. by spin on glass (SOG) or a CVD oxide is performed as illustrated in FIG. 14d.

In the next step the second main surface is worked (not shown) on which, to start with, the zone for the large surface area radiation entrance window and guard rings, where necessary, are opened, on which the p-type epi layer is deposited and patterned as described above. This is followed by metallization, preferably with TiN and aluminum before, in the end, the structures are covered all over with a protective layer of photoresist.

Now, the protective layer SOG plus TO on the first main surface is etched off at all locations where contacts to the n-type epi layer E1 of the bulk need to be produced. In the transistor region this is a contact hole in the center intended to produce the connection of the inner gate G2 to outer gate G1. After this, the contact holes are etched away on the first main surface and the metallization carried out preferably with TiN and aluminum as illustrated in FIG. 14d. Lastly, the photoresist is removed from both main surfaces.

The completed device is an SDD with a circular JFET comprising centrally a metallic connection of the inner gate G2 to the outer gate G1. Since high temperature steps are no longer needed in this method in accordance with the invention after epi deposition, it is particularly soft and suitable for the production of low-noise detectors.

The methods and devices described have been selected purely by way of example in explaining the gist of the invention and represent no limitation. Thus, together with detectors and transistors other electronic circuit elements such as capacitors, resistors or diodes can be fabricated with the aid of one or more epi layers and otherwise conductive layers, for the integration of which preferably the rim area of the detectors is suitable.

In particular it is possible in sense to use a semiconductor body with p-type conductivity and to alter the doping of the epi layers accordingly. It may also prove to be particularly advantageous to vary the doping profile within the epi layers to optimize special properties of the components. Furthermore, an advantage may materialize from selecting a commercially available bulk of silicon which already comprises a complex layer structure which may be epi layers or also a combination of epi layers and insulating layers. By suitably selecting the crystal orientation of the bulk too, it is possible to adapt the technology to special requirements, especially in application of anisotropic etching methods.

Although particularly in the second method in selecting the example embodiments preference was given to transistors provided on the first main surface of an SDD, it is understood, of course, that both main surfaces of a detector can be patterned simultaneously or in sequence in accordance with this method. In some cases combining the first method with the second method may prove particularly of advantage. Also, describing the application as regards SDDs is not to be interpreted as being a limitation, this instead simply being selected by way of example. The method is also excellently suited to fabricate CCDs, especially pn-CCDs and pixel detectors with integrated electronic components since the steps in fabrication for these devices are practically identical with those of SDDs.

Likewise, silicon as the material of choice for the detector represents no limitation to the gist of the invention. Accordingly, the method can be applied just as well to other semiconductors such as germanium, cadmium telluride or gallium arsenide, etc, whereby the methods as suitable for these materials are to be applied for patterning. It is just as possible to deposit epi layers on semiconductor materials other than that of the bulk so as to combine the advantages of the various materials. Thus, for instance, the electronic components may be structured as described in epi silicon applied to a bulk better suitable for absorbing the radiation.

Although methods in accordance with embodiments of the invention avoid ion implantation as a doping method for fabricating areas of the first and second conductivity type, it may prove to be advantageous to put this to use locally to tailor the properties of the detectors and electronic components. Thus, for instance, by additional implantation doping in the rim the breakdown voltage of junctions produced by the method in accordance with the invention can be increased. Furthermore, it could well be of advantage to make use of the implantation dping to create drift structures whilst the entry window is produced by epitaxy.

All publications and existing systems mentioned in this specification are herein incorporated by reference.

Although certain methods and products constructed in accordance with the teachings of the invention have been described herein, the scope of coverage of this patent is not limited thereto. On the contrary, this patent covers all embodiments of the teachings of the invention fairly falling within the scope of the appended claims either literally or under the doctrine of equivalents.

1. A method of fabricating a semiconductor radiation detector, comprising the steps of:
providing a semiconductor body of a first conductivity type adapted to detect radiation, said semiconductor body having a first main surface and an opposite second main surface, and
forming further semiconductor layers of a second conductivity type and the first conductivity type, respectively, on at least one of the first and second main surfaces of the semiconductor body,
wherein at least one of the further semiconductor layers, functioning as a radiation entrance window, is formed as a highly-doped layer of the second conductivity type on the first main surface, and said layer being formed by epitaxy and doped in situ.

2.-40. (canceled)

41. The method as set forth in claim 1, wherein at least one of the further semiconductor layers functioning as a back contact of the first conductivity type is formed on the second main surface by epitaxy.

42. The method as set forth in claim 1, wherein the further layers of the first and second conductivity type are formed on the second main surface by epitaxy.

43. The method as set forth in claim 1, wherein at least one further layer of the second conductivity type is formed and patterned on the second main surface, and at least one layer of the first conductivity type is formed on the second main surface and insulated from the layer of the second conductivity type.

44. The method as set forth in claim 42, wherein at least one layer of the first conductivity type on the second main surface is configured concentric or spirally surrounded by at least one layer of the second conductivity type insulated therefrom.

45. The method as set forth in claim 42, wherein on the second main surface at least one concentric or spiral layer of the second conductivity type is configured surrounded by at least one layer of the first conductivity type insulated therefrom.

46. The method as set forth in claim 1, wherein on at least one of the main surfaces patterned layers of the first and second conductivity type are formed juxtaposed and/or superposed.

47. The method as set forth in claim 1, wherein at least one layer of the second conductivity type is formed on the first main surface with a doping gradient.

48. The method as set forth in claim 1, wherein further epi layers for connecting radiation detectors are formed with or as electronic components and particularly as active and/or passive electronic components and/or as conducting paths.

49. The method as set forth in claim 1, wherein additional electronic components are integrated monolithically on the detectors and are fabricated simultaneously with the detectors.

50. The method as set forth in claim 1, wherein selective epitaxy is employed for patterning semiconductor layers.

51. The method as set forth in claim 1, wherein for fabrication of guard structures the same epi layers are used as for fabrication of the drift rings on the first main surface or radiation entrance window on the second main surface.

52. The method as set forth in claim 1, wherein for integrating transistors, preferably JFETs and bipolar transistors in semiconductor radiation detectors, one or more epi layers of the second conductivity type and first conductivity type are deposited, patterned, insulated and interconnected in sequence on the first main surface of a semiconductor body of the first conductivity type preferably with a higher doped epi layer of the first conductivity type in the region of the first main surface and provided with a patterned insulating layer.

53. The method as set forth in claim 1, wherein for integrating transistors, preferably JFETs and bipolar transistors in semiconductor radiation detectors, one or more epi layers of the second conductivity type and first conductivity type are deposited in sequence within one single working step, and then patterned, insulated and inerconnected on the first main surface of a semiconductor body of the first conductivity type preferably with a higher doped epi layer of the first conductivity type in the region of the first main surface and provided with a patterned insulating layer.

54. The method as set forth in claim 1, wherein one or more epi layers for fabricating the electronic components are also used for fabricating detector zones and guard structures.

55. A semiconductor radiation detector, comprising:
a semiconductor body of a first conductivity type for detecting-radiation, said semiconductor body having a first main surface and an opposite second main surface, and
further semiconductor layers of a second conductivity type and the first conductivity type, respectively, formed on at least one of the first and second main surfaces of the semiconductor body,
wherein at least one of the further semiconductor layers, functioning as a radiation entrance window, is formed as a highly-doped layer of the second conductivity type on the first main surface, and said layer being a doped epitaxial layer.

56. The semiconductor radiation detector as set forth in claim 55, wherein at least one of the further semiconductor layers functioning as a back contact of the first conductivity type is formed on the second main surface by epitaxy.

57. The semiconductor radiation detector as set forth in claim 55, wherein the further layers of the first and second conductivity type are formed on the second main surface by epitaxy.

58. The semiconductor radiation detector as set forth in claim 55, wherein at least one further layer of the second conductivity type is formed and patterned on the second main surface, and at least one layer of the first conductivity type is formed on the second main surface and insulated from the layer of the second conductivity type.

59. The semiconductor radiation detector as set forth in claim 57, wherein at least one layer of the first conductivity type on the second main surface is configured concentric or spirally surrounded by at least one layer of the second conductivity type insulated therefrom.

60. The semiconductor radiation detector as set forth in claim 57, wherein on the second main surface at least one concentric or spiral layer of the second conductivity type is configured surrounded by at least one layer of the first conductivity type insulated therefrom.

61. The semiconductor radiation detector as set forth in claim 55, wherein on at least one of the main surfaces patterned layers of the first and second conductivity type are formed juxtaposed and/or superposed.

62. The semiconductor radiation detector as set forth in claim 55, wherein at least one layer of the second conductivity type is formed on the first main surface with a doping gradient.

63. The semiconductor radiation detector as set forth in claim 55, wherein provided on the first main surface are drift structures and structures for voltage reduction of at least one epi layer of the second conductivity type and that the semiconductor radiation detector comprises as a radiation entrance window and for voltage reduction on the second main surface at least one epi layer of the second conductivity type.

64. The semiconductor radiation detector as set forth in claim 62, wherein it comprises in the anode region a metallization of the semiconductor body or of the epi layer of the first conductivity type deposited thereon, preferably of TiN and aluminum.

65. The semiconductor radiation detector as set forth in claim 55, wherein it comprises in the region of the drift zone and in the rim a resistive layer of an epi layer of the second conductivity type.

66. The semiconductor radiation detector as set forth in claim 55, wherein it comprises on the second main surface, in the region of the radiation entrance window and in the rim a resistive layer of an epi layer of the second conductivity type.

67. The semiconductor radiation detector as set forth in claim 55, wherein the anode is located at the edge of the drift zone.

68. The semiconductor radiation detector as set forth in claim 67, wherein the anode at the edge of the drift zone is surrounding it in the form of a closed or interrupted ring.

69. The semiconductor radiation detector comprising a plurality of cells, as set forth in claim 68, wherein the plurality of cells have a common anode.

70. The semiconductor radiation detector as set forth in claim 55, wherein it is configured to form drift structures of at least one epi layer of the second conductivity type and that it comprises closed rings, spirals, spirally connected rings or closed surface areas directly connected to the semiconductor body.

71. The semiconductor radiation detector as set forth in claim 55, wherein it is configured to form guard structures for reduction of high electrical voltages of at least one epi layer of the second conductivity type and that it comprises closed rings, spirals, spirally connected rings or closes surface areas directly connected to the semiconductor body.

72. The semiconductor radiation detector as set forth in claim 55, wherein it is configured to form guard structures for reduction of high electrical voltages of at least one epi layer of the first or second conductivity type and that it comprises sheet areas, spirals or spirally connected rings deposited on an insulating layer and bonded internally to the region of high voltage and at the rim to the semiconductor body.

73. The semiconductor radiation detector as set forth in claim 55, wherein it is configured to form a pn CCD with a semiconductor body of the first conductivity type on the first main surface with zones of at least one epi layer of the first and second conductivity type and that at least one epi layer of the second conductivity type is deposited on the second main surface as a radiation entrance window and for voltage reduction.

74. The semiconductor radiation detector as set forth in claim 55, wherein for forming a pixel detector with a semiconductor body of the first conductivity type on the first main surface with zones of at least one epi layer of the first and second conductivity type and that at least one epi layer of the second conductivity type is deposited on the second main surface as a radiation entrance window and for voltage reduction.

75. The semiconductor radiation detector as set forth in claim 55, wherein it is configured for forming structures for draining electrons under the oxide with epi layers of the first and second conductivity type and that it comprises spirals or spirally connected rings on the oxide.

76. The semiconductor radiation detector as set forth in claim 55, wherein the semiconductor body is preferably made of Si, Ge, diamond, GaAs, AlGaAs, CdTe or other heterogenous semiconductors and that semiconductor layers of the semiconductor body or of another semiconductor are used as the epi layers.

77. The semiconductor radiation detector as set forth in claim 55, wherein it comprises in the edge portion of the radiation entrance window an additional doping by ion implantation.

78. The semiconductor radiation detector as set forth in claim 55, wherein a thin layer of a dielectric layer, preferably thermal silicon oxide, is provided on the epi layer of the second
conductivity type serving as the radiation entrance window.
